(19) United States
(12) Patent Application Publication
(10) Pub. No.: US 2015/0333075 A1
(43) Pub. Date: Nov. 19, 2015

(54) Semiconductor Device

(71) Applicant: Samsung Electronics Co., Ltd., Suwon-si (KR)

(72) Inventors: Seol-Un Yang, Gwacheon-si (KR); Sung-Bong Kim, Suwon-si (KR); Seung-Han Park, Gunpo-si (KR)

(21) Appl. No.: 14/704,130

(22) Filed: May 5, 2015

(30) Foreign Application Priority Data
May 19, 2014 (KR) 10-2014-0059751

(51) Int. Cl. H01L 27/11; H01L 29/36; H01L 29/06; H01L 27/088; H01L 27/092

(52) U.S. Cl. CPC H01L 27/1104; H01L 27/0886; H01L 27/0924; H01L 29/0649; H01L 29/36

(57) ABSTRACT

A semiconductor device, which can improve reading and writing stability of a static random access memory (SRAM) is provided. The semiconductor device includes a substrate having a first region and a second region defined therein, a first fin type active pattern formed on the substrate, extending in a first direction and including a first part and a second part, in the first region, the second part being disposed in the first direction at both sides of the first part, a second fin type active pattern formed on the substrate, extending in a second direction and having a third part and a fourth part, in the second region, the fourth part being disposed in the second direction at both sides of the third part and recessed relative to the third part, a first gate electrode extending in a third direction different from the first direction and formed on the first part, a second gate electrode extending in a fourth direction different from the second direction and formed on the third part, a first source/drain formed in the second part and doped with a first type impurity, and a second source/drain including a first epitaxial layer doped with the first type impurity and formed on the fourth part.

### CROSS-REFERENCE TO RELATED APPLICATION

This U.S. non-provisional patent application claims priority under 35 U.S.C. §119 to Korean Patent Application No. 10-2014-0059751, filed on May 19, 2014, in the Korean Intellectual Property Office, the disclosure of which is hereby incorporated by reference in its entirety.

### BACKGROUND

The present disclosure generally relates to the field of electronics and, more particularly, to semiconductor devices.

As one of scaling techniques for increasing the density of integrated circuit devices, a multi-gate transistor has been proposed, in which a fin-shaped silicon body is formed on a substrate and a gate is then formed on a surface of the silicon body.

Since the multi-gate transistor uses a three-dimensional (3D) channel, scaling of the multi-gate transistor may be easy. In addition, current controlling capability may be improved without increasing a gate length of the multi-gate transistor. Further, a short channel effect (SCE), in which an electric potential of a channel region is affected by a drain voltage, may be effectively reduced or possibly suppressed.

### SUMMARY

Some embodiments provide semiconductor devices, which can improve reading and writing stability of a static random access memory (SRAM).

According to some embodiments, there is provided a semiconductor device comprises a substrate having a first region and a second region defined therein, a first fin type active pattern formed on the substrate, extending in a first direction and including a first part and a second part, in the first region, the second part being disposed in the first direction at both sides of the first part, a second fin type active pattern formed on the substrate, extending in a second direction and including a third part and a fourth part, in the second region, the fourth part being disposed in the second direction at both sides of the third part and recessed relative to the third part, a first gate electrode formed on the first part and extending in a third direction different from the first direction, a second gate electrode formed on the third part and extending in a fourth direction different from the second direction, a first source/drain formed in the second part and doped with a first type impurity, and a second source/drain formed on the fourth part and including a first epitaxial layer doped with the first type impurity.

A top surface of the first part is substantially co-planar with a top surface of the second part.

A top surface of the first fin type active pattern upwardly protrudes relative to a top surface of a field insulation layer formed on the substrate, and the first source/drain further includes a second epitaxial layer formed on a top surface of the second part and a sidewall of the second part upwardly protruding relative to the top surface of the field insulation layer.

The first epitaxial layer and the second epitaxial layer include the same material each other.

A doping depth of the first type impurity from the top surface of the first part is less than a doping depth of the first type impurity from the top surface of the third part.

A doping depth of the first type impurity from the top surface of the first part is substantially equal to a doping depth of the first type impurity from the top surface of the third part.

The first type impurity is a p type impurity.

The first region is an SRAM region and the second region is a logic region.

According to some embodiments, there is provided a semiconductor device including a first fin type active pattern extending in a first direction and including a first part and a second part, on a substrate, the second part being disposed in the first direction at both sides of the first part, a second fin type active pattern extending in the first direction and including a third part and a fourth part, on the substrate, the fourth part being disposed in the first direction at both sides of the third part and recessed relative to the third part, a gate electrode formed on the first part and the third part and extending in a second direction different from the first direction, a first source/drain formed in the second part and doped with a first type impurity, and a second source/drain formed on the fourth part and including a first epitaxial layer doped with a second type impurity different from the first type impurity.

A top surface of the first part is substantially co-planar with a top surface of the second part.

A top surface of the first fin type active pattern upwardly protrudes relative to a top surface of a field insulation layer formed on the substrate, and the first source/drain further includes a second epitaxial layer formed on a top surface of the second part and a sidewall of the second part upwardly protruding relative to the top surface of the field insulation layer.

The first epitaxial layer and the second epitaxial layer include different materials each other.

A doping depth of the first type impurity from the top surface of the first part is less than a doping depth of the second type impurity from the top surface of the third part.

A doping depth of the first type impurity from the top surface of the first part is substantially equal to a doping depth of the second type impurity from the top surface of the third part.

The first type impurity is a p type impurity and the second type impurity is an n type impurity.

According to some embodiments, there is provided a semiconductor device including a substrate having a first region and a second region defined therein, a first fin type transistor formed on the first region and including a first fin type active pattern, a first gate electrode crossing the first fin type active pattern on the first fin type active pattern, and a first source/drain formed at both sides of the first gate electrode and doped with a first type impurity, and a second fin type transistor formed on the second region and including a second fin type active pattern, a second gate electrode crossing the second fin type active pattern on the second fin type active pattern, and a second source/drain formed at both sides of the second gate electrode and doped with a second type impurity, wherein a first doping depth of the first type impurity from a top surface of the first fin type active pattern overlapping with the first gate electrode is different from a second doping depth of the second type impurity from a top surface of the second fin type active pattern overlapping with the second gate electrode.

The first fin type transistor further includes a first recess which is formed in the first fin type active pattern at both sides of the first gate electrode, the second fin type transistor further includes a second recess which is formed in the second fin type active pattern at both sides of the second gate electrode, and wherein the first source/drain includes a first epitaxial layer formed in the first recess, and the second source/drain includes a second epitaxial layer formed in the second recess.

Each of the first type impurity and the second type impurity is a p type impurity, and the first region is an SRAM region and the second region is a logic region.

The first type impurity is a p type impurity and the second type impurity is an n type impurity, and the first fin type transistor is a pull-up transistor of SRAM, and the second fin type transistor is a pull-down transistor or a pass transistor of SRAM.

The second depth is greater than the first depth.

### BRIEF DESCRIPTION OF THE DRAWINGS

The above and other features and advantages of present inventive concept will become more apparent by describing in detail some embodiments thereof with reference to the attached drawings, in which:

FIGS. 1 and 2 illustrate a circuit view and a layout view of semiconductor devices according to some embodiments of the present inventive concept;

FIG. 3 illustrates a layout view of a semiconductor device according to some embodiments of the present inventive concept;

FIG. 4 illustrates perspective views of the regions I, II and III of FIG. 3;

FIG. 5 illustrates cross-sectional views taken along the lines A-A, B-B and C-C of FIG. 3;

FIG. 6 illustrates a cross-sectional view taken along the line D-D of FIG. 3;

FIG. 7 illustrates cross-sectional views for comparing depths of doped impurities at portions taken along the lines A-A and B-B of FIG. 3;

FIG. 8 illustrates cross-sectional views of a semiconductor device according to some embodiments of the present inventive concept;

FIGS. 9 to 11 illustrate a semiconductor device according to some embodiments of the present inventive concept;

FIG. 12 illustrates cross-sectional views of a semiconductor device according to some embodiments of the present inventive concept;

FIGS. 13 and 14 illustrate a semiconductor device according to some embodiments of the present inventive concept;

FIGS. 15 and 16 illustrate a semiconductor device according to some embodiments of the present inventive concept;

FIG. 17 illustrates a diagram of a semiconductor device according to some embodiments of the present inventive concept;

FIG. 18 illustrates perspective views of the semiconductor device of FIG. 17;

FIG. 19 illustrates cross-sectional views taken along the lines the E-E and F-F of FIG. 18;

FIG. 20 illustrates cross-sectional views of a semiconductor device according to some embodiments of the present inventive concept;

FIGS. 21 and 22 illustrate a semiconductor device according to some embodiments of the present inventive concept;

FIG. 23 illustrates cross-sectional views of a semiconductor device according to some embodiments of the present inventive concept;

FIGS. 24 and 25 illustrate a semiconductor device according to some embodiments of the present inventive concept;

FIG. 26 illustrates a diagram of a semiconductor device according to some embodiments of the present inventive concept;

FIG. 27 illustrates perspective views of the semiconductor device of FIG. 26;

FIG. 28 illustrates cross-sectional views taken along the lines E-E, F-F and G-G of FIG. 27;

FIG. 29 illustrates a block diagram of an electronic system including semiconductor devices according to some embodiments of the present inventive concept; and

FIGS. 30 and 31 illustrate example semiconductor systems to which semiconductor devices according to some embodiments of the present inventive concept can be applied.

### DETAILED DESCRIPTION

The present inventive concept will now be described more fully hereinafter with reference to the accompanying drawings, in which preferred embodiments are shown. This disclosure may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or terms provided herein is intended merely to better illuminate the invention and is not a limitation on the scope of the invention unless otherwise specified. Further, unless defined otherwise, all terms defined in generally used dictionaries may not be overly interpreted.

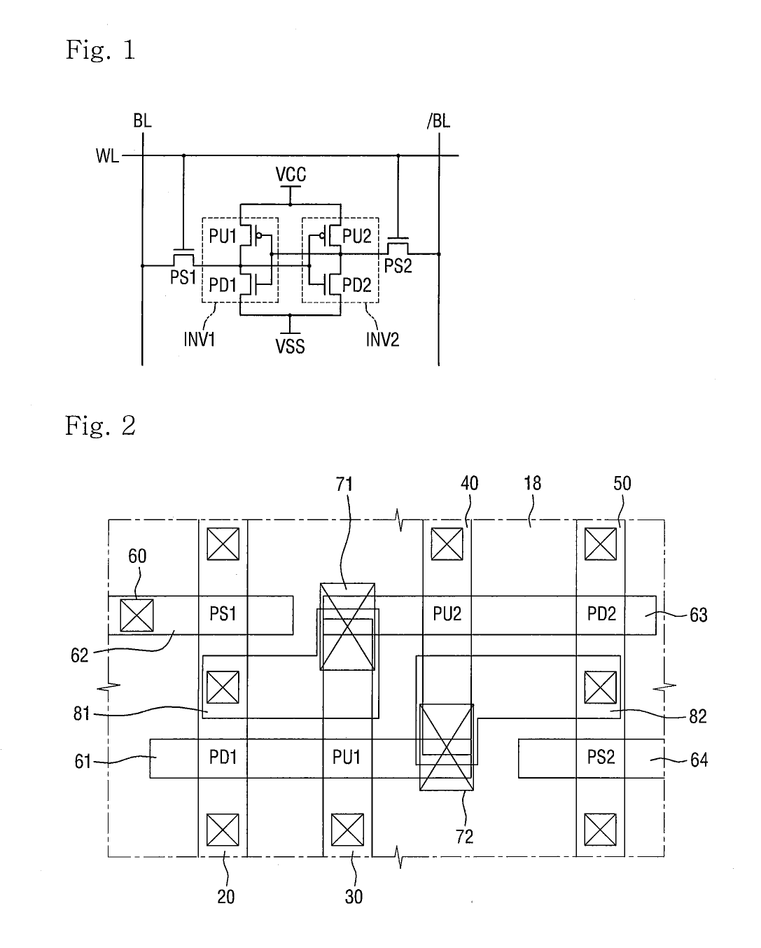

Hereinafter, a circuit view and a layout view of semiconductor devices according to some embodiments will be described with reference to FIGS. 1 and 2.

FIGS. 1 and 2 are a circuit view and a layout view of semiconductor devices according to some embodiments of the present inventive concept.

Referring to FIGS. 1 and 2, each of the semiconductor devices according to some embodiments may include a pair of inverters INV1 and INV2 connected in parallel between a power supply node Vcc and a ground node Vss, a first pass transistor PS1 and a second pass transistor PS2 connected to output nodes of the inverters INV1 and INV2, respectively. The first pass transistor PS1 and the second pass transistor PS2 may be connected to a bit line BL and a complementary bit line/BL, respectively. Gates of the first pass transistor PS1 and the second pass transistor PS2 may be connected to a word line WL.

In some embodiments, the first inverter INV1 includes a first pull-up transistor PU1 and a first pull-down transistor PD1 connected in series to each other, and the second inverter INV2 includes a second pull-up transistor PU2 and a second pull-down transistor PD2 connected in series to each other. The first pull-up transistor PU1 and the second pull-up transistor PU2 may be PMOS transistors, and the first pull-down transistor PD1 and the second pull-down transistor PD2 may be NMOS transistors.

In addition, in order to constitute a latch circuit, an input node of the first inverter INV1 is connected to an output node of the second inverter INV2 and an input node of the second inverter INV2 is connected to an output node of the first inverter INV1.

Referring to FIGS. 1 and 2, a first active region 20, a second active region 30, a third active region 40 and a fourth active region 50, which are spaced apart from one another, may extend lengthwise in one direction (e.g., in an up-and-down direction of FIG. 2). The second active region 30 and the third active region 40 may extend in smaller lengths than the first active region 20 and the fourth active region 50.

In addition, a first conductive line 61, a second conductive line 62, a third conductive line 63, and a fourth conductive line 64 extend in the other direction (for example, in a left-and-right direction of FIG. 2) to intersect the first active region 20 to the fourth active region 50. In some embodiments, the first conductive line 61 completely intersects the first active region 20 and the second active region 30 while partially overlapping with a terminal of the third active region 40. The third conductive line 63 completely intersects the fourth active region 50 and the third active region 40 while partially overlapping with a terminal of the second active region 30. The second conductive line 62 and the fourth conductive line 64 intersect the first active region 20 and the fourth active region 50, respectively.

As shown, the first pull-up transistor PU1 is defined in vicinity of an intersection of the first conductive line 61 and the second active region 30, the first pull-down transistor PD1 is defined in vicinity of an intersection of the first conductive line 61 and the first active region 20, and the first pass transistor PS1 is defined in vicinity of an intersection of the second conductive line 62 and the first active region 20. The second pull-up transistor PU2 is defined in vicinity of an intersection of the third conductive line 63 and the third active region 40, the second pull-down transistor PD2 is defined in vicinity of an intersection of the third conductive line 63 and the fourth active region 50, and the second pass transistor PS2 is defined in vicinity of an intersection of the fourth conductive line 64 and the fourth active region 50.

Sources/drains may be formed at opposite sides of the respective intersections of the first to fourth conductive lines 61 to 64 and the first to fourth active regions 20, 30, 40 and 50.

In addition, a plurality of contacts 60 may be formed.

Further, a shared contact 71 may connect the second active region 30, the third conductive line 63 and a wire 81. A shared contact 72 may also connect the third active region 40, the first conductive line 61 and the wire 82.

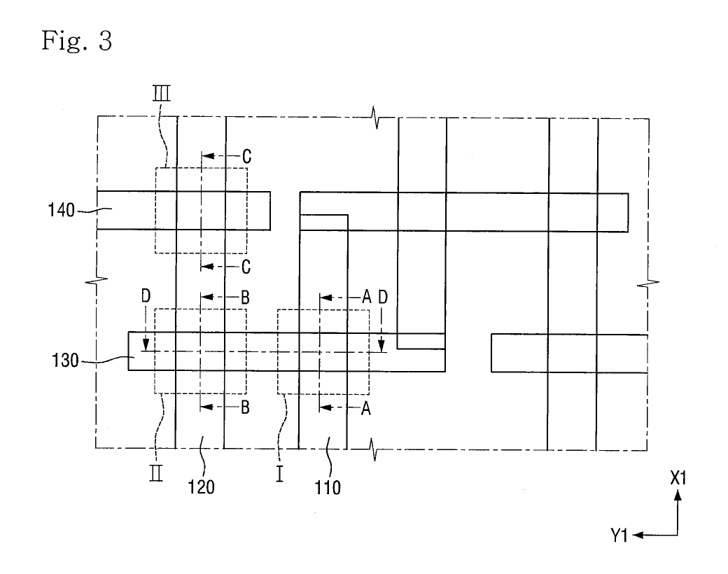

A semiconductor device according to some embodiments will be described with reference to FIGS. 3 to 7.

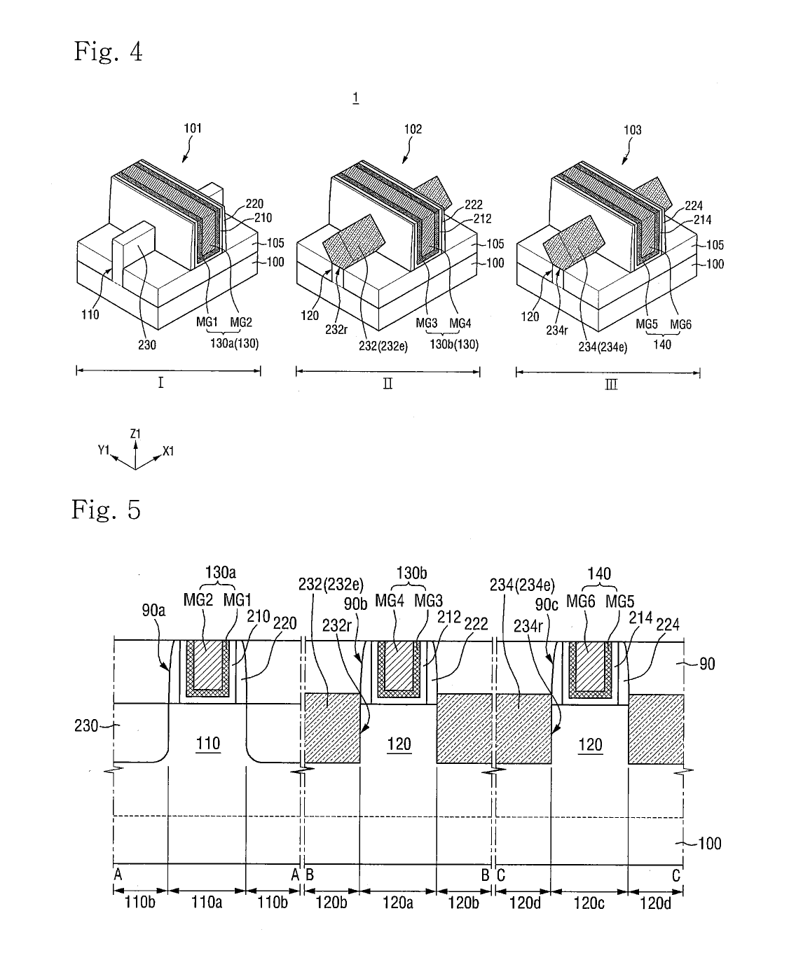

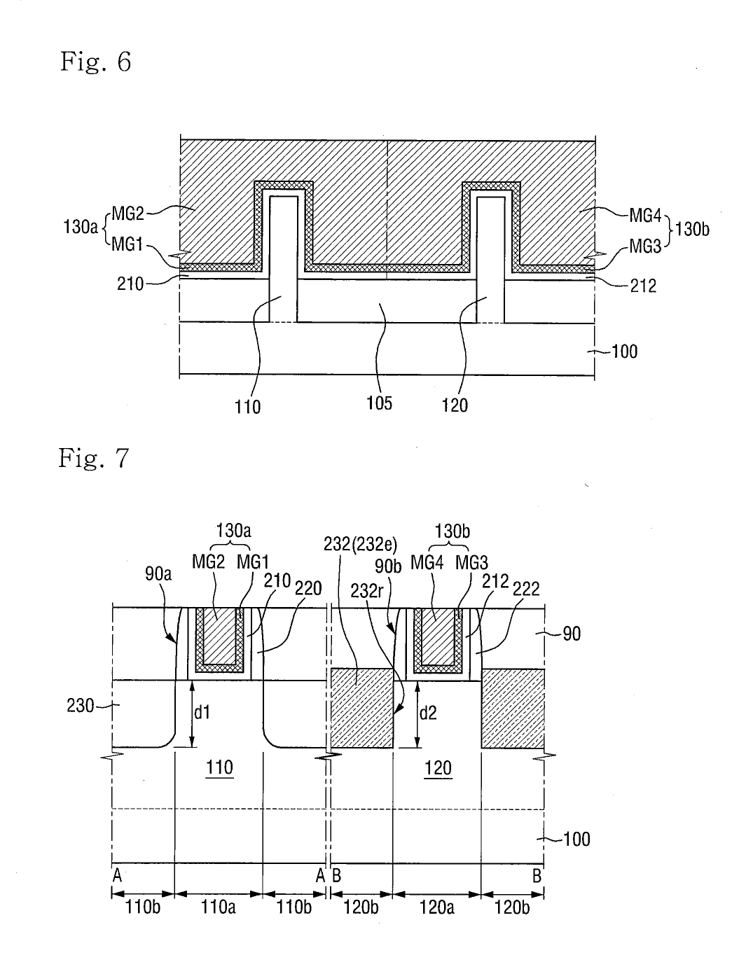

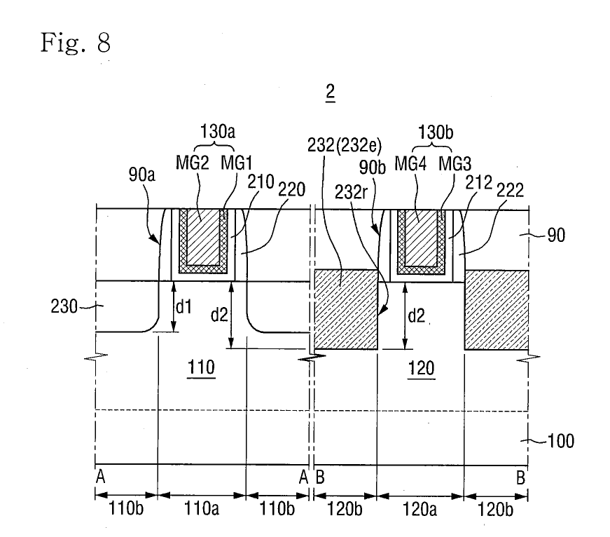

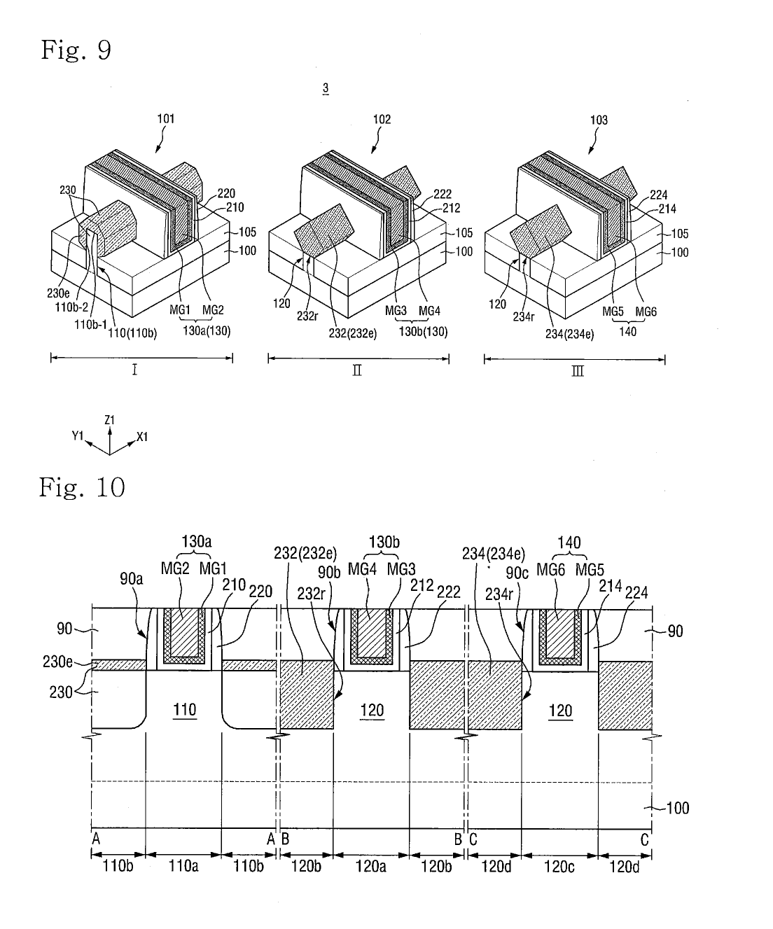

FIG. 3 is a layout view of a semiconductor device according to some embodiments of the present inventive concept, FIG. 4 illustrates perspective views of the regions I, II and III of FIG. 3, FIG. 5 illustrates cross-sectional views taken along the lines A-A, B-B and C-C of FIG. 3, FIG. 6 is a cross-sectional view taken along the line D-D of FIG. 3 and FIG. 7 illustrates cross-sectional views for comparing depths of doped impurities at portions taken along the lines A-A and B-B of FIG. 3. For purposes of description, only a plurality of fin type active patterns and a plurality of gate electrodes are illustrated in FIG. 3 and an interlayer insulation layer 90 is not illustrated in FIG. 4.

Referring to FIGS. 3 to 7, the semiconductor device 1 according to some embodiments may include a first fin type active pattern 110, a second fin type active pattern 120, a first gate electrode structure 130, a second gate electrode structure 140, a first source/drain 230 and a second source/drain 232.

The substrate 100 may be a bulk silicon wafer or a silicon-on-insulator (SOI). Alternatively, the substrate 100 may be a silicon substrate or may include a material other than silicon. For example, the substrate 100 may include at least one of germanium, silicon germanium, indium antimonide, a lead telluride compound, indium arsenic, indium phosphide, gallium arsenic, gallium antimonide, or other suitable substrate materials, but not limited thereto. Alternatively, the substrate 100 may include an epitaxial layer formed on a base substrate.

The first fin type active pattern 110 and the second fin type active pattern 120 may be formed on the substrate 100 while protruding from the substrate 100. The field insulation layer 105 may cover portions of sidewalls of the first fin type active pattern 110 and the second fin type active pattern 120. Therefore, at least a portion of a top surface of the first fin type active pattern 110 and at least a portion of a top surface of the second fin type active pattern 120 may upwardly protrude relative to a top surface of the field insulation layer 105 formed on the substrate 100.

The first fin type active pattern 110 and the second fin type active pattern 120 defined by the field insulation layer 105 may extend lengthwise in a first direction X1. The first fin type active pattern 110 and the second fin type active pattern 120 may be formed in parallel to be adjacent to each other.

The field insulation layer 105 may include, for example, at least one of an oxide layer, a nitride layer, an oxynitride layer and a combination thereof.

The first fin type active pattern 110 and the second fin type active pattern 120 may be portions of the substrate 100 or may include an epitaxial layer grown from the substrate 100. The first fin type active pattern 110 and the second fin type active pattern 120 may include, for example, silicon or germanium as an element semiconductor material. In addition, the first fin type active pattern 110 and the second fin type active pattern 120 may include a compound semiconductor, for example, a group IV-IV compound semiconductor or a group III-V compound semiconductor. In some embodiments, the first fin type active pattern 110 and the second fin type active pattern 120 may include a group IV-IV compound semiconductor including, for example, a binary compound or a ternary compound including at least two elements of carbon (C), silicon (Si), germanium (Ge), and tin (Sn) or a compound doped with a IV group element. The first fin type active pattern 110 and the second fin type active pattern 120 may include a group III-V compound semiconductor including, for example, a binary compound, a ternary compound or a quaternary compound, prepared by combining at least one group III element of aluminum (Al), gallium (Ga) and indium (In) with at least one group V element of phosphorus (P), arsenic (As) and antimony (Sb).

In the following description of semiconductor devices according to embodiments, it is assumed that each of the first fin type active pattern 110 and the second fin type active pattern 120 includes silicon.

The first gate electrode structure 130 extends in a second direction Y1 and is formed to cross the first fin type active pattern 110 and the second fin type active pattern 120. The second gate electrode structure 140 extends in the second direction Y1 and is formed to cross the second fin type active pattern 120. However, the second gate electrode structure 140 does not cross the first fin type active pattern 110.

The first gate electrode structure 130 includes a first gate electrode 130a and a second gate electrode 130b. In the first gate electrode structure 130, the first gate electrode 130a is a region formed to cross the first fin type active pattern 110, and the second gate electrode 130b is a region formed to cross the second fin type active pattern 120. The first gate electrode 130a and the second gate electrode 130b are connected to each other.

The second gate electrode structure 140 includes a third gate electrode 140. The third gate electrode 140 is a region formed to cross the second fin type active pattern 120.

In the semiconductor device 1 according to some embodiments, the substrate 100 may have a first region I, a second region II and a third region III. The first region I may be a region at which the first fin type active pattern 110 and the first gate electrode structure 130 cross each other, the second region II may be a region at which the second fin type active pattern 120 and the first gate electrode structure 130 cross each other. In addition, the third region III may be a region at which the second fin type active pattern 120 and the second gate electrode structure 140 cross each other.

In more detail, the first region I may be a region at which the first fin type active pattern 110 and the first gate electrode 130a cross each other, the second region II may be a region at which the second fin type active pattern 120 and the second gate electrode 130b cross each other, and the third region III may be a region at which the second fin type active pattern 120 and the third gate electrode 140 cross each other.

A first fin type transistor 101 may be formed in the first region I, a second fin type transistor 102 may be formed in the second region II, and a third fin type transistor 103 may be formed in the third region III.

For example, when the first to third regions I, II and III are matched to the semiconductor device shown in FIGS. 1 and 2, they may be included in an SRAM region. In addition, the first region I may be a region where a pull-up transistor of SRAM is formed, the second region II may be a region where a pull-down transistor of SRAM is formed, and the third region III may be a region where a pass transistor of SRAM is formed.

The following description will focus on the first to third fin type transistors 101, 102 and 103.

Referring to FIGS. 3 to 7, the first fin type transistor 101 includes a first fin type active pattern 110, a first gate electrode 130a and a first source/drain 230. The second fin type transistor 102 includes a second fin type active pattern 120, a second gate electrode 130b and a second source/drain 232. The third fin type transistor 103 includes a second fin type active pattern 120, a third gate electrode 140 and a third source/drain 234.

The first fin type active pattern 110 includes a first part 110a and a second part 110b. The second part 110b of the first fin type active pattern 110 is disposed at both sides of the first part 110a of the first fin type active pattern 110 in the first direction X1.

A top surface of the first part 110a of the first fin type active pattern 110 and a top surface of the second part 110b of the first fin type active pattern 110 upwardly protrude relative to a top surface of the field insulation layer 105. In addition, the top surface of the first part 110a of the first fin type active pattern 110 and the top surface of the second part 110b of the first fin type active pattern 110 may be substantially co-planar with each other.

The second fin type active pattern 120 included in the second fin type transistor 102 includes a first part 120a and a second part 120b. The second fin type active pattern 120 included in the third fin type transistor 103 includes a third part 120c and a fourth part 120d. The second part 120b of the second fin type active pattern 120 is disposed at both sides of the first part 120a of the second fin type active pattern 120 in the first direction X1, and the fourth part 120d of the second fin type active pattern 120 is disposed at both sides of the third part 120c of the second fin type active pattern 120 in the first direction X1.

The second part 120b of the second fin type active pattern 120 and the fourth part 120d of the second fin type active pattern 120, positioned between the second gate electrode 130b and the third gate electrode 140, may be directly connected to each other. In other words, the second part 120b of the second fin type active pattern 120 and the fourth part 120d of the second fin type active pattern 120, positioned between the second gate electrode 130b and the third gate electrode 140, may be parts shared by the second fin type transistor 102 and the third fin type transistor 103.

A top surface of the first part 120a of the second fin type active pattern 120 and a top surface of the third part 120c of the second fin type active pattern 120 upwardly protrude relative to a top surface of the field insulation layer 105.

In addition, a top surface of the second part 120b of the second fin type active pattern 120 may be recessed relative to the top surface of the first part 120a of the second fin type active pattern 120. That is to say, a height ranging from the substrate 100 to the top surface of the first part 120a of the second fin type active pattern 120 is greater than a height ranging from the substrate 100 to the top surface of the second part 120b of the second fin type active pattern 120.

A top surface of the fourth part 120d of the second fin type active pattern 120 may be recessed relative to the top surface of the top surface of the third part 120c of the second fin type active pattern 120.

The first gate electrode 130a as a portion of the first gate electrode structure 130 may be formed on the first fin type active pattern 110 and the field insulation layer 105. For example, the first gate electrode 130a may be formed on the first part 110a of the first fin type active pattern 110.

The second gate electrode 130b as a portion of the first gate electrode structure 130 may be formed on the second fin type active pattern 120 and the field insulation layer 105. For example, the second gate electrode 130b may be formed on the first part 120a of the second fin type active pattern 120.

That is to say, the first gate electrode structure 130 may be formed on the first part 110a of the first fin type active pattern 110 and the first part 120a of the second fin type active pattern 120. The first gate electrode structure 130 may overlap with the first part 110a of the first fin type active pattern 110 and the first part 120a of the second fin type active pattern 120.

The third gate electrode 140 may be formed on the second fin type active pattern 120 and the field insulation layer 105. For example, the third gate electrode 140 may be formed on the third part 120c of the second fin type active pattern 120. The third gate electrode 140 may overlap with the third part 120c of the second fin type active pattern 120.

The first gate electrode 130a may include first and second metal layers MG1 and MG2, the second gate electrode 130b may include third and fourth metal layers MG3 and MG4, and the third gate electrode 140 may include fifth and sixth metal layers MG5 and MG6. As shown, the first gate electrode 130a, the second gate electrode 130b and the third gate electrode 140 may include two or more metal layers stacked, but aspects of embodiments are not limited thereto.

Each of the first metal layer MG1, the third metal layer MG3 and the fifth metal layer MG5 may adjust a work function. The second metal layer MG2, the fourth metal layer MG4 and the sixth metal layer MG6 may fill spaces produced by the first metal layer MG1, the third metal layer MG3 and the fifth metal layer MG5, respectively. Each of the first metal layer MG1, the third metal layer MG3 and the fifth metal layer MG5 may include, for example, at least one of TiN, TaN, TiC, and TaC. In addition, each of the second metal layer MG2, the fourth metal layer MG4 and the sixth metal layer MG6 may include W or Al.

In addition, each of the first gate electrode 130a, the second gate electrode 130b and the third gate electrode 140 may include a non-metal material, e.g., Si or SiGe. The first gate electrode 130a, the second gate electrode 130b and the third gate electrode 140 may be formed by, for example, a replacement process, but aspects of embodiments are not limited thereto.

A first gate insulation layer 210 may be formed between the first fin type active pattern 110 and the first gate electrode 130a, a second gate insulation layer 212 may be formed between the second fin type active pattern 120 and the second gate electrode 130b, and a third gate insulation layer 214 may be formed between the second fin type active pattern 120 and the third gate electrode 140.

The first gate insulation layer 210 may be formed along the top surface and sidewalls of the first part 110a of the first fin type active pattern 110, and the second gate insulation layer 212 may be formed along the top surface and sidewalls of the top surface and sidewalls of the first part 120a of the second fin type active pattern 120. In addition, since a region of the second fin type transistor 102 shown in FIG. 4 may be substantially the same with the third fin type transistor 103, the third gate insulation layer 214 may be formed along the top surface and sidewalls of the third part 120c of the second fin type active pattern 120.

In addition, the first gate insulation layer 210 and the second gate insulation layer 212 may be disposed between the first gate electrode structure 130 and the field insulation layer 105, and the third gate insulation layer 214 may be disposed between the third gate electrode 140 and the field insulation layer 105.

In addition, the first gate insulation layer 210 and the second gate insulation layer 212 may be connected to each other while making direct contact with each other.

The first to third gate insulation layers 210, 212 and 214 may include a high-k material having a higher dielectric constant than a silicon oxide layer. For example, the first to third gate insulation layers 210, 212 and 214 may include one or more selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, but aspects of embodiments are not limited thereto.

A first gate spacer 220 may be formed on sidewalls of the first gate electrode 130a, a second gate spacer 222 may be formed on sidewalls of the second gate electrode 130b, and a third gate spacer 224 may be formed on sidewalls of the third gate electrode 140. In other words, since the first gate spacer 220 and the second gate spacer 222 are formed on sidewalls of the first gate electrode structure 130, the first gate spacer 220 and the second gate spacer 222 may be connected to each other.

The first to third gate spacer 220, 222 and 224 may include, for example, at least one of silicon nitride (SiN), silicon oxynitride (SiON), silicon oxide (SiO₂), silicon oxycarbonitride (SiOCN), and combinations thereof.

The first to third gate spacer 220, 222 and 224 may be formed of a single layer, but aspects of embodiments are not limited thereto. The first to third gate spacer 220, 222 and 224 may have a multi-layered structure.

The first recess 232r may be formed in the second fin type active pattern 120 disposed at both sides of the second gate electrode 130b. Specifically, the first recess 232r may be formed in the second part 120b of the second fin type active pattern 120. The second recess 234r may be formed in the second fin type active pattern 120 disposed at opposite sides of the third gate electrode 140. Specifically, the second recess 234r may be formed in the fourth part 120d of the second fin type active pattern 120.

The second part 120b of the second fin type active pattern 120 and the fourth part 120d of the second fin type active pattern 120, positioned between the second gate electrode 130b and the third gate electrode 140, may be directly connected to each other. Therefore, the first recess 232r and the second recess 234r, positioned between the second gate electrode 130b and the third gate electrode 140, may be parts shared by the second fin type transistor 102 and the third fin type transistor 103.

The first source/drain 230 may be formed in the first fin type active pattern 110 disposed at both sides of the first gate electrode 130a. Specifically, the first source/drain 230 may be formed in the second part 110b of the first fin type active pattern 110. The first source/drain 230 may include, for example, a doped p type impurity.

The second source/drain 232 may be formed in the second fin type active pattern 120 disposed at both sides of the second gate electrode 130b. Specifically, the second source/drain 232 may be formed in the second part 120b of the second fin type active pattern 120.

The third source/drain 234 may be formed in the second fin type active pattern 120 disposed at both sides of the third gate electrode 140. Specifically, the third source/drain 234 may be formed in the fourth part 120d of the second fin type active pattern 120. The second source/drain 232 and the third source/drain 234 may include, for example, a doped n type impurity.

The second source/drain 232 may include a first epitaxial layer 232e formed in the first recess 232r, and the third source/drain 234 may include a second epitaxial layer 234e formed in the second recess 234r.

A height ranging from the top surface of the substrate 100 to the top surface of the first epitaxial layer 232e may be greater than a height ranging from the top surface of the substrate 100 to the top surface of the first part 120a of the second fin type active pattern 120, and a height ranging from the top surface of the substrate 100 to the top surface of the second epitaxial layer 234e may be greater than a height ranging from the top surface of the substrate 100 to the top surface of the third part 120c of the second fin type active pattern 120. In other words, the second source/drain 232 and the third source/drain 234 may be elevated sources/drains, respectively.

The second source/drain 232 and the third source/drain 234, positioned between the second gate electrode 130b and the third gate electrode 140, may be sources/drains shared by the second fin type transistor 102 and the third fin type transistor 103. In other words, the first epitaxial layer 232e and the second epitaxial layer 234e, positioned between the second gate electrode 130b and the third gate electrode 140, may be connected to each other.

Since the second source/drain 232 and the third source/drain 234 may include, for example, an n type impurity, the second fin type transistor 102 and the third fin type transistor 103 may be n-type fin type transistors.

The first epitaxial layer 232e and the second epitaxial layer 234e may include the same material each other. For example, the first epitaxial layer 232e and the second epitaxial layer 234e may include the same material as the substrate 100 or a tensile stress material. For example, when the substrate 100 includes Si, the first epitaxial layer 232e and the second epitaxial layer 234e may include Si or a material having a smaller lattice constant than Si (e.g., SiC).

Outer circumferential surfaces of the first epitaxial layer 232e and the second epitaxial layer 234e may have various shapes. For example, the outer circumferential surfaces of the first epitaxial layer 232e and the second epitaxial layer 234e may have at least one of a diamond shape, a circular shape and a rectangular shape. In FIG. 4, the first epitaxial layer 232e and the second epitaxial layer 234e shaped of a diamond (or a pentagon or a hexagon) are illustrated by way of example.

A depth of the p type impurity doped into the first source/drain 230 is a first depth d1 from the top surface of the first part 110a of the first fin type active pattern 110. As shown in FIG. 7, in the semiconductor device 1 according to some embodiments, the depth d1 of the p type impurity doped in to the first source/drain 230 may be a depth ranging from the top surface of the first part 110a of the first fin type active pattern 110 to a dopant line (that is, a bottommost part) of the first source/drain 230.

A depth of the n type impurity doped into the second source/drain 232 is a second depth d2 from the top surface of the first part 120a of the second fin type active pattern 120. For ease of description, FIG. 7 illustrates that the depth d2 of the n type impurity doped into the second source/drain 232 corresponds to the depth ranging from the top surface of the first part 120a of the second fin type active pattern 120 to the dopant line of the second source/drain 232, that is, to the bottommost part of the first epitaxial layer 232e, but aspects of embodiments are not limited thereto.

In the semiconductor device 1 according to some embodiments, the depth d1 of the p type impurity doped into the first source/drain 230 may be substantially equal to the depth d2 of the n type impurity doped into the second source/drain 232, but aspects of embodiments are not limited thereto.

Although not shown in FIG. 7, in the third fin type transistor 103, the depth of the n type impurity doped into the third source/drain 234 may correspond to the depth d2 ranging from the top surface of the third part 120c of the second fin type active pattern 120.

The interlayer insulation layer 90 is formed on the substrate 100. The interlayer insulation layer 90 may cover the first fin type active pattern 110, the second fin type active pattern 120, the first source/drain 230, the second source/drain 232, the third source/drain 234 and the field insulation layer 105. The interlayer insulation layer 90 may include a first trench 90a, a second trench 90b and a third trench 90c located corresponding to the first gate electrode 130a, the second gate electrode 130b and the third gate electrode 140, respectively.

That is to say, the first gate electrode 130a is formed in the first trench 90a, the second gate electrode 130b is formed in the second trench 90b and the third gate electrode 140 is formed in the third trench 90c.

In addition, the first gate insulation layer 210 may be formed along sidewalls and a bottom surface of the first trench 90a, the second gate insulation layer 212 may be formed along sidewalls and a bottom surface of the second trench 90b and the third gate insulation layer 214 may be formed along sidewalls and a bottom surface of the third trench 90c.

The interlayer insulation layer 90 may include, for example, at least one of a low-k material, an oxide layer, a nitride layer and an oxynitride layer. Examples of the low-k material may include flowable oxide (FOX), tonen silazene (TOSZ), undoped silicate glass (USG), borosilica glass (BSG), phosphosilaca glass (PSG), borophosphor silica glass (BPSG), plasma enhanced tetraethyl orthosilicate (PETEOS), fluoride silicate glass (FSG), high density plasma (HDP) oxide, plasma enhanced oxide (PEOX), flowable CVD (FCVD) oxide, or combinations thereof, but not limited thereto.

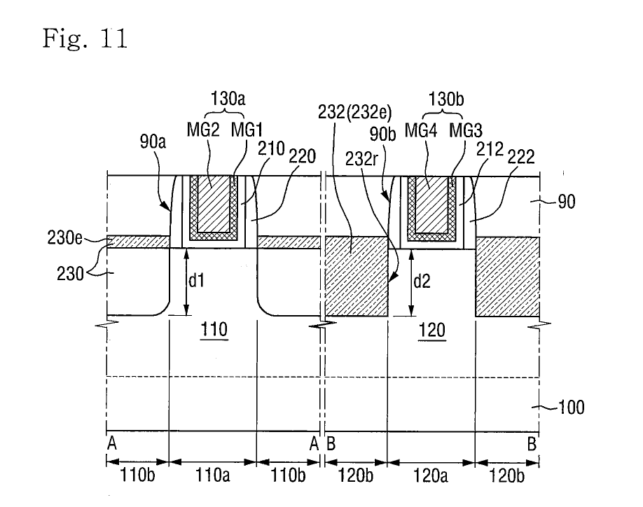

FIG. 8 illustrates cross-sectional views of a semiconductor device 2 according to some embodiments of the present inventive concept. For ease of description, the following description will focus on differences between the semiconductor device 1 of FIG. 4 and the semiconductor device 2 of FIG. 8.

Referring to FIG. 8, a depth d1 of a p type impurity doped into a first source/drain 230 is different from a depth d2 of an n type impurity doped into a second source/drain 232.

In the semiconductor device 2 according to some embodiments the depth d1 of a p type impurity doped into a first source/drain 230 is less than the depth d2 of an n type impurity doped into a second source/drain 232.

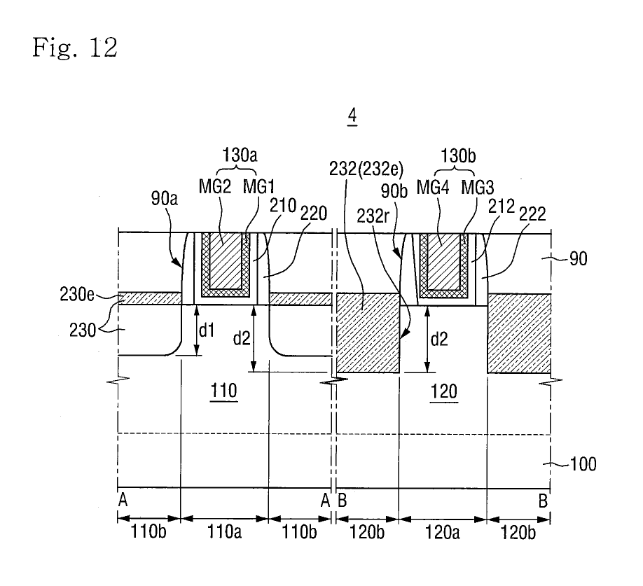

Next, a semiconductor device 3 according to some embodiments will be described with reference to FIGS. 3 and 9 to 11. For ease of description, the following description will focus on differences between the semiconductor device 1 of FIG. 4 and the semiconductor device 3 of FIG. 9.

FIGS. 9 to 11 illustrate a semiconductor device according to some embodiments of the present inventive concept. In detail, FIG. 9 illustrates perspective views illustrating the regions I, II and III of FIG. 3, FIG. 10 illustrates cross-sectional views taken along the lines A-A, B-B and C-C of FIG. 3, and FIG. 11 illustrates cross-sectional views for comparing depths of doped impurities at portions taken along the lines A-A and B-B of FIG. 3. For ease of description, an interlayer insulation layer 90 is not illustrated in FIG. 9.

Referring to FIGS. 9 to 11, in a first fin type transistor 101, a first source/drain 230 further includes a third epitaxial layer 230e.

The third epitaxial layer 230e is formed at both sides of a first gate electrode 130a. For example, the third epitaxial layer 230e is formed on a second part 110b of a first fin type active pattern 110. The third epitaxial layer 230e may include a doped p type impurity.

A top surface of the first fin type active pattern 110 may upwardly protrude relative to a top surface of a field insulation layer 105. Therefore, the third epitaxial layer 230e may be formed on sidewalls 110b-2 and a top surface 110b-1 of the second part 110b of the first fin type active pattern 110 upwardly protruding relative to the top surface of the field insulation layer 105. That is to say, the third epitaxial layer 230e may be formed along the periphery of the second part 110b of the first fin type active pattern 110 upwardly protruding relative to the top surface of the field insulation layer 105.

When the first fin type active pattern 110 includes Si, the third epitaxial layer 230e may include SiGe, Si or a material having a smaller lattice constant than Si (e.g., SiC).

For example, the third epitaxial layer 230e, the first epitaxial layer 232e and the second epitaxial layer 234e may include different materials from each other, but aspects of embodiments are not limited thereto.

In the semiconductor device 3 according to some embodiments, a depth d1 of a p type impurity doped into a first source/drain 230 based on a top surface of a first part 110a of the first fin type active pattern 110 may be substantially equal to a depth d2 of an n type impurity doped into a second source/drain 232 based on the top surface of the first part 120a of the second fin type active pattern 120.

A height ranging from a top surface of a substrate 100 to a top surface of a first epitaxial layer 232e may be equal to a height ranging from the top surface of the substrate 100 to a top surface of a second epitaxial layer 234e, and a height ranging from the top surface of the substrate 100 to the top surface of the first epitaxial layer 232e may be equal to a height ranging from the top surface of the substrate 100 to a top surface of a third epitaxial layer 230e, but aspects of the present invention are not limited thereto.

The top surface of the first epitaxial layer 232e may be higher than the top surface of the first part 120a of the second fin type active pattern 120, and the top surface of the second epitaxial layer 234e may be higher than the top surface of the third part 120c of the second fin type active pattern 120. In addition, the top surface of the third epitaxial layer 230e may be higher than the top surface of the first part 110a of the first fin type active pattern 110.

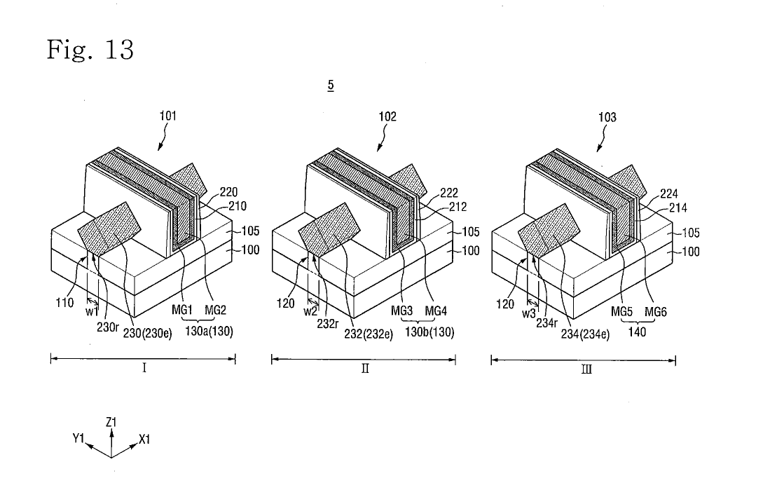

FIG. 12 illustrates cross-sectional views of a semiconductor device 4 according to some embodiments of the present inventive concept. For ease of description, the following description will focus on differences between the semiconductor device 3 of FIG. 9 and the semiconductor device 4 of FIG. 12.

Referring to FIG. 12, a depth d1 of a p type impurity doped into a first source/drain 230 is different from a depth d2 of an n type impurity doped into a second source/drain 232.

In the semiconductor device 4 according to some embodiments the depth d2 of the n type impurity doped into the second source/drain 232 is greater than the depth d1 of the p type impurity doped into the first source/drain 230.

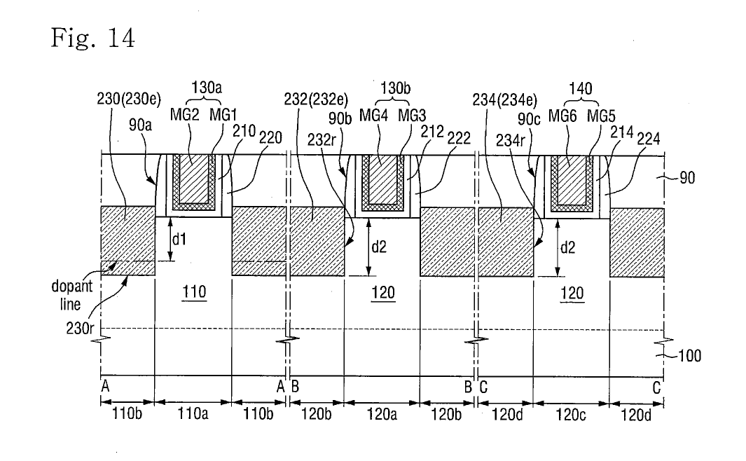

Next, a semiconductor device 5 according to some embodiments will be described with reference to FIGS. 3, 13 and 14. For ease of description, the following description will focus on differences between the semiconductor device 1 of FIG. 4 and the semiconductor device 5 of FIG. 13.

FIGS. 13 and 14 illustrate a semiconductor device according to some embodiments of the present inventive concept. In detail, FIG. 13 illustrates perspective views of the regions I, II and III of FIG. 3 and FIG. 14 illustrates cross-sectional views taken along the lines A-A, B-B and C-C of FIG. 3.

Referring to FIGS. 13 and 14, a first fin type transistor 101 includes a third recess 230r and a first source/drain 230 formed in the third recess 230r.

A first fin type active pattern 110 includes a first part 110a and a second part 110b. A top surface of the second part 110b of the first fin type active pattern 110 is recessed relative to a top surface of the first part 110a of the first fin type active pattern 110. That is to say, a height ranging from the substrate 100 to the top surface of the first part 110a of the first fin type active pattern 110 is greater than a height ranging from the substrate 100 to the top surface of the second part 110b of the first fin type active pattern 110.

The third recess 230r may be formed in the first fin type active pattern 110 disposed at both sides of a first gate electrode 130a. Specifically, the third recess 230r may be formed in the second part 110b of the first fin type active pattern 110.

A first source/drain 230 may be formed on the first fin type active pattern 110 disposed at both sides of a first gate electrode 130a. Specifically, the first source/drain 230 may be formed on the second part 110b of the first fin type active pattern 110. The first source/drain 230 may include, for example, a doped p type impurity.

The first source/drain 230 may include a third epitaxial layer 230e formed in the third recess 230r. In the semiconductor device 5 according to some embodiments, outer circumferential surfaces of the third epitaxial layer 230e may have at least one of a diamond shape, a circular shape and a rectangular shape. In FIG. 13, the third epitaxial layer 230e shaped of a diamond (or a pentagon or a hexagon) is illustrated by way of example.

In the semiconductor device 5 according to some embodiments, the third epitaxial layer 230e may include a compressive stress material. For example, the compressive stress material may be a material having a greater lattice constant than silicon (Si), e.g., SiGe. The compressive stress material may improve mobility of carriers of a channel region by applying compressive stress to the first fin type active pattern 110 (e.g., the first part 110a of the first fin type active pattern 110).

A depth of the p type impurity doped into the first source/drain 230 is a first depth d1 from the top surface of the first part 110a of the first fin type active pattern 110. The p type impurity included in the first source/drain 230 may be doped into a portion of the third epitaxial layer 230e. That is to say, the p type impurity included in the first source/drain 230 may not be doped to the bottommost part of the third epitaxial layer 230e.

In other words, a height ranging from the top surface of the first part 110a of the first fin type active pattern 110 to the bottommost part of the third epitaxial layer 230e may be greater than a height ranging from the top surface of the first part 110a of the first fin type active pattern 110 to the dopant line of the p type impurity doped into the first source/drain 230.

A depth of an n type impurity doped into the second source/drain 232 is a second depth d2 based on the top surface of the first part 120a of the second fin type active pattern 120. For ease of description, FIG. 14 illustrates that the depth d2 of the n type impurity doped into the second source/drain 232 corresponds to the depth ranging from the top surface of the first part 120a of the second fin type active pattern 120 to the dopant line of the second source/drain 232, that is, to the bottommost part of the first epitaxial layer 232e, but aspects of the present invention are not limited thereto.

Although not shown in FIG. 14, in the third fin type transistor 103, the depth of the n type impurity doped into the third source/drain 234 may correspond to the depth d2 ranging based on the top surface of the third part 120c of the second fin type active pattern 120.

The depth d1 of the p type impurity doped into the first source/drain 230 is different from the depth d2 of the n type impurity doped into the second source/drain 232. In the semiconductor device 5 according to some embodiments the depth d1 of the p type impurity doped into the first source/drain 230 is less than the depth d2 of the n type impurity doped into the second source/drain 232.

FIG. 14 illustrates that a height ranging from the bottommost part of the first epitaxial layer 232e to the top surface of the first part 120a of the second fin type active pattern 120 is the same with a height ranging from the bottommost part of the third epitaxial layer 230e to the top surface of the first part 110a of the first fin type active pattern 110, but aspects of embodiments are not limited thereto.

The height ranging from the bottommost part of the first epitaxial layer 232e to the top surface of the first part 120a of the second fin type active pattern 120 may be different from the height ranging from the bottommost part of the third epitaxial layer 230e to the top surface of the first part 110a of the first fin type active pattern 110. If the height ranging from the bottommost part of the first epitaxial layer 232e to the top surface of the first part 120a of the second fin type active pattern 120 is smaller than the height ranging from the bottommost part of the third epitaxial layer 230e to the top surface of the first part 110a of the first fin type active pattern 110, the p type impurity may be entirely doped into the third epitaxial layer 230e.

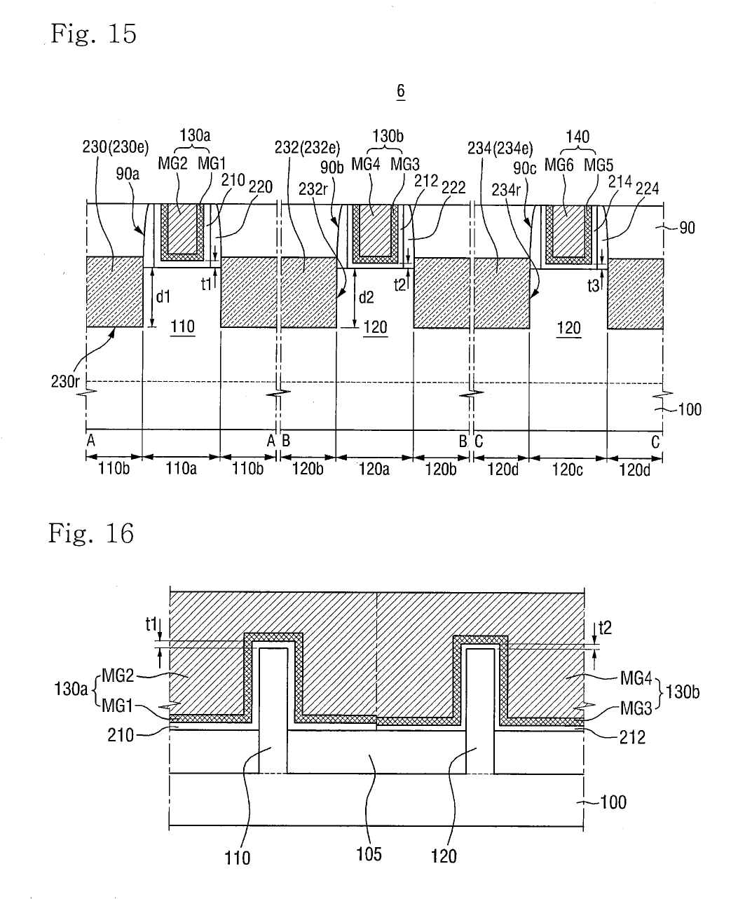

Next, a semiconductor device 6 according to some embodiments will be described with reference to FIGS. 3, 13, 15 and 16. For ease of description, the following description will focus on differences between the semiconductor device 5 of FIG. 13 and the semiconductor device 6 of FIG. 15.

FIGS. 15 and 16 illustrate a semiconductor device 6 according to some embodiments of the present inventive concept. In detail, FIG. 15 illustrates cross-sectional views taken along lines A-A, B-B and C-C of FIG. 3, and FIG. 16 illustrates a cross-sectional view taken along the line D-D of FIG. 3.

Referring to FIGS. 13, 15 and 16, a thickness t1 of a first gate insulation layer 210 and a thickness t2 of a second gate insulation layer 212 may be different from each other. In addition, the thickness t2 of the second gate insulation layer 212 may be substantially equal to a thickness t3 of a third gate insulation layer 214.

In the semiconductor device 6 according to some embodiments the thickness t1 of the first gate insulation layer 210 is greater than each of the thickness t2 of the second gate insulation layer 212 and the thickness t3 of the third gate insulation layer 214.

Each of the first fin type active pattern 110 and the second fin type active pattern 120 may have long sides which extend in a first direction X1 and short sides which extend in a second direction Y1, respectively.

A short side width of the first fin type active pattern 110 is a first width w1 in a first region I, a short side width of the second fin type active pattern 120 in a second region II is a second width w2, and a short side width of the second fin type active pattern 120 in a third region III is a third width w3.

In the semiconductor device 6 according to some embodiments the short side width w1 of the first fin type active pattern 110 in the first region I, the short side width w2 of the first fin type active pattern 110 in the second region II, and the short side width w3 of the second fin type active pattern 120 in the third region III may be substantially equal to one another.

In the semiconductor device 6 according to some embodiments, the depth d1 of the p type impurity doped into the first source/drain 230 may be substantially equal to the depth d2 of the n type impurity doped into the second source/drain 232, but aspects of embodiments are not limited thereto.

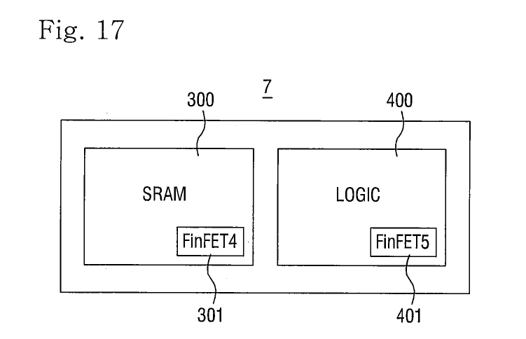

Next, a semiconductor device 7 according to some embodiments of the present inventive concept will be described with reference to FIGS. 17 to 19.

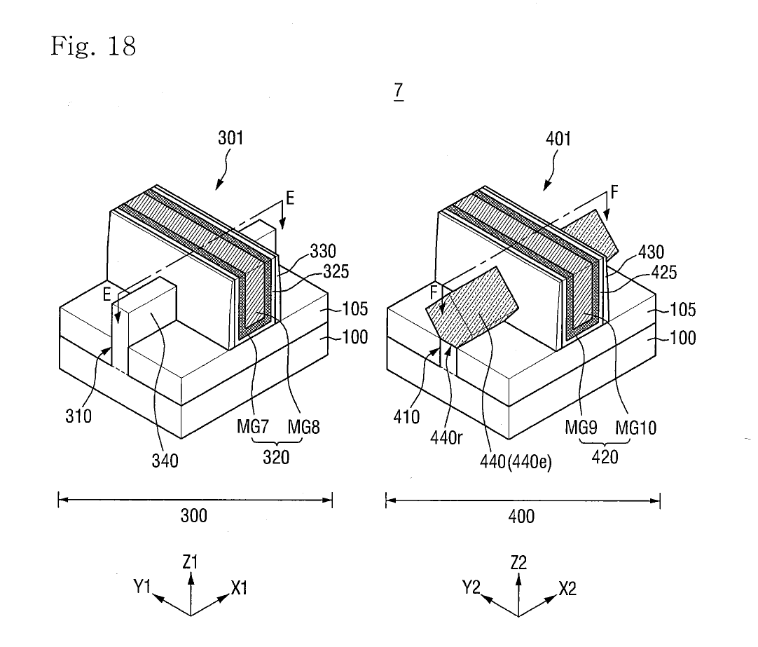

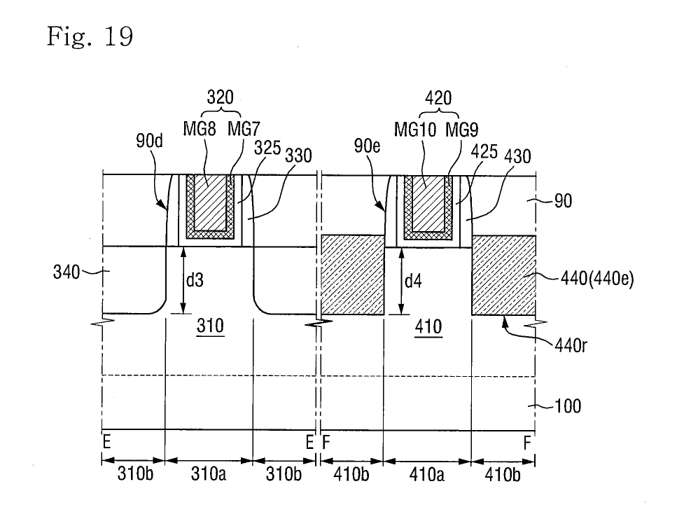

FIG. 17 is a diagram of the semiconductor device 7, FIG. 18 illustrates perspective views of the semiconductor device 7, and FIG. 19 illustrates cross-sectional views taken along the lines E-E and F-F of FIG. 18.

Referring to FIG. 17, in the semiconductor device 7 according to some embodiments, a fourth fin type transistor 301 may be disposed on an SRAM region 300 and a fifth fin type transistor 401 may be disposed on a logic region 400.

The fourth fin type transistor 301 and the fifth fin type transistor 401 may be of the same type, that is, n type or p type transistors. In the semiconductor device 7 according to some embodiments, it is assumed that the fourth fin type transistor 301 and the fifth fin type transistor 401 are p type transistors.

In FIG. 17, the SRAM region 300 and the logic region 400 are illustrated by way of example, but not limited thereto.

Referring to FIGS. 18 and 19, the fourth fin type transistor 301 includes a third fin type active pattern 310, a fourth gate electrode 320, and a fourth source/drain 340. The fifth fin type transistor 401 includes a fourth fin type active pattern 410, a fifth gate electrode 420 and a fifth source/drain 440.

In the semiconductor device 7 according to some embodiments, the fourth fin type transistor 301 is substantially the same with the first fin type transistor 101 of the semiconductor device 1 according to some embodiments shown in FIGS. 3 to 7, and repeated descriptions thereof will not be given.

The fourth fin type active pattern 410 may be formed on the substrate 100 while protruding from the substrate 100. Since the field insulation layer 105 covers portions of sidewalls of the fourth fin type active pattern 410, at least a portion of a top surface of the fourth fin type active pattern 410 may upwardly protrude relative to a top surface of the field insulation layer 105.

The fourth fin type active pattern 410 defined by the field insulation layer 105 may extend lengthwise in a third direction X2.

The fourth fin type active pattern 410 includes a first part 410a and a second part 410b. The second part 410b of the fourth fin type active pattern 410 is disposed at both sides of the first part 410a of the fourth fin type active pattern 410 in the third direction X2.

In addition, a top surface of the second part 410b of the fourth fin type active pattern 410 is recessed relative to a top surface of the first part 410a of the fourth fin type active pattern 410. That is to say, a height ranging from the substrate 100 to the top surface of the first part 410a of the fourth fin type active pattern 410 is greater than a height ranging from the substrate 100 to the top surface of the second part 410b of the fourth fin type active pattern 410.

The fifth gate electrode 420 extends in a fourth direction Y2 and is formed to cross the fourth fin type active pattern 410. The fifth gate electrode 420 may be formed on the fourth fin type active pattern 410 and the field insulation layer 105. For example, the fifth gate electrode 420 may be formed on the first part 410a of the fourth fin type active pattern 410.

The fifth gate electrode 420 may include ninth and tenth metal layers MG9 and MG10. As shown, the fifth gate electrode 420 may include two or more layers stacked, but aspects of embodiments are not limited thereto.

The fifth gate insulation layer 425 may be formed between the fourth fin type active pattern 410 and the fifth gate electrode 420. The fifth gate insulation layer 425 may be formed along a top surface and sidewalls of the first part 410a of the fourth fin type active pattern 410. In addition, the fifth gate insulation layer 425 may be disposed between the fifth gate electrode 420 and the field insulation layer 105.

The fourth recess 440r may be formed in the fourth fin type active pattern 410 disposed at both sides of the fifth gate electrode 420. Specifically, the fourth recess 440r may be formed in the second part 410b of the fourth fin type active pattern 410.

The fifth source/drain 440 may be formed on the fourth fin type active pattern 410 disposed at the opposite sides of the fifth gate electrode 420. The fifth source/drain 440 may be formed on the second part 410b of the fourth fin type active pattern 410.

Since a p type impurity may be doped into the fourth source/drain 340, the fifth source/drain 440 may include, for example, a doped p type impurity.

The fifth source/drain 440 may include a fourth epitaxial layer 440e formed in the fourth recess 440r.

A height ranging from a top surface of the substrate 100 to the top surface of the fourth epitaxial layer 440e may be greater than a height ranging from the top surface of the substrate 100 to a top surface of the first part 410a of the fourth fin type active pattern 410. That is to say, the fifth source/drain 440 may be an elevated source/drain.

The fourth epitaxial layer 440e may include a compressive stress material. For example, the compressive stress material may be a material having a greater lattice constant than silicon (Si), e.g., SiGe. The compressive stress material may improve mobility of carriers of a channel region by applying compressive stress to the fourth fin type active pattern 410 (e.g., the first part 410a of the fourth fin type active pattern 410).

An outer circumferential surface of the fourth epitaxial layer 440e may have various shapes. For example, the outer circumferential surface of the fourth epitaxial layer 440e may have at least one of a diamond shape, a circular shape and a rectangular shape. In FIG. 18, the fourth epitaxial layer 440e shaped of a diamond (or a pentagon or a hexagon) is illustrated by way of example.

A depth of the p type impurity doped into the fourth source/drain 340 is a third depth d3 based on a top surface of the first part 310a of the third fin type active pattern 310. A depth of the p type impurity doped into the fifth source/drain 440 is a fourth depth d4 based on a top surface of the first part 410a of the fourth fin type active pattern 410.

In the semiconductor device 7 according to some embodiments, the depth d3 of the p type impurity doped into the fourth source/drain 340 may be substantially equal to the depth d4 of the p type impurity doped into the fifth source/drain 440, but aspects of embodiments are not limited thereto.

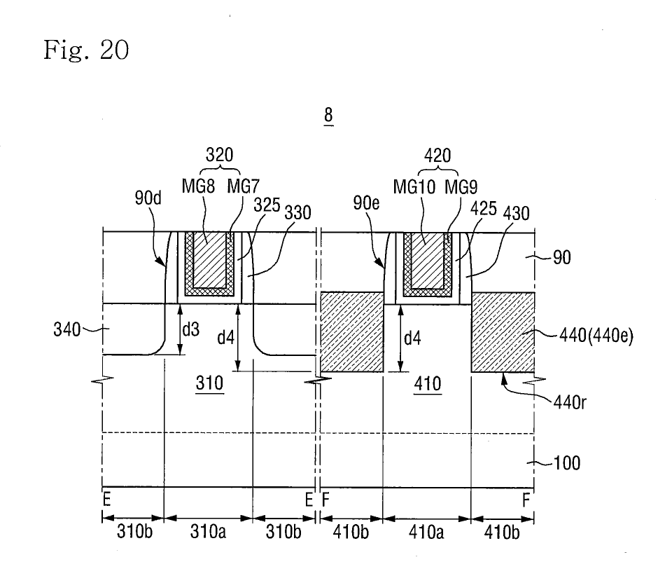

FIG. 20 illustrates cross-sectional views of a semiconductor device 8 according to some embodiments of the present inventive concept. For ease of description, the following description will focus on differences between the semiconductor device 7 of FIG. 17 and the semiconductor device 8 of FIG. 20.

Referring to FIG. 20, the depth d3 of the p type impurity doped into the fourth source/drain 340 is different from the depth d4 of the p type impurity doped into the fifth source/drain 440.

In the semiconductor device 8 according to some embodiments, the depth d3 of the p type impurity doped into the fourth source/drain 340 is less than the depth d4 of the p type impurity doped into the fifth source/drain 440.

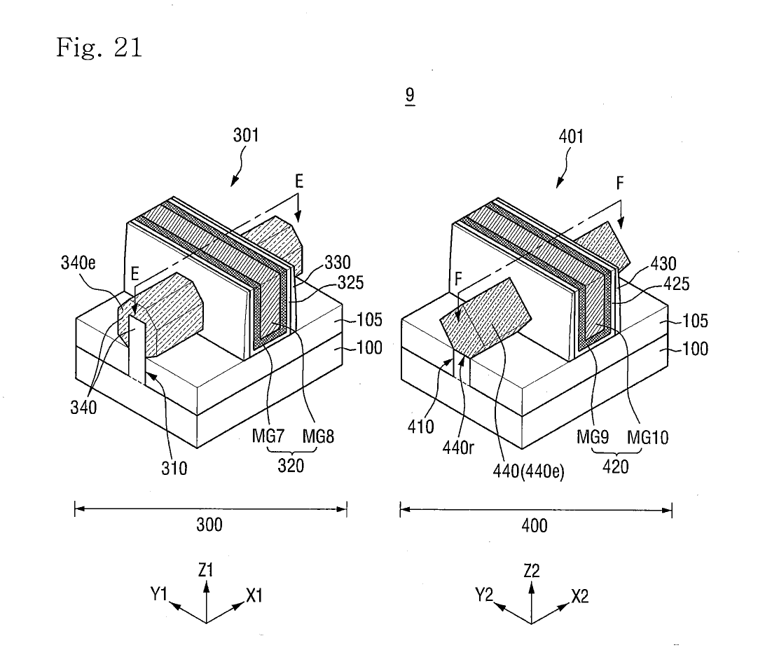

FIGS. 21 and 22 illustrate a semiconductor device 9 according to some embodiments of the present inventive concept. For ease of description, the following description will focus on differences between the semiconductor device 7 of FIG. 17 and the semiconductor device 9 of FIG. 21. In detail, FIG. 21 illustrates perspective views of the semiconductor device 9, and FIG. 22 illustrates cross-sectional views taken along the lines E-E and F-F of FIG. 21.

Referring to FIGS. 21 and 22, in a fourth fin type transistor 310, a fourth source/drain 340 may further include a fifth epitaxial layer 340e.

The fifth epitaxial layer 340e is formed at both sides of a fourth gate electrode 320. For example, the fifth epitaxial layer 340e is formed on a second part 310b of a third fin type active pattern 310. The fifth epitaxial layer 340e may include a doped p type impurity.

A top surface of the third fin type active pattern 310 upwardly protrudes relative to a top surface of a field insulation layer 105. Therefore, the fifth epitaxial layer 340e may be formed on sidewalls and a top surface of the second part 310b of the third fin type active pattern 310 upwardly protruding relative to the top surface of the field insulation layer 105. That is to say, the fifth epitaxial layer 340e may be formed along the periphery of the second part 310b of the third fin type active pattern 310 upwardly protruding relative to the top surface of the field insulation layer 105.

When the third fin type active pattern 310 includes Si, the fifth epitaxial layer 340e may include SiGe, Si or a material having a less lattice constant than Si (e.g., SiC).

For example, the fifth epitaxial layer 340e may include the same material as the fourth epitaxial layer 440e, but aspects of embodiments are not limited thereto.

In the semiconductor device 9 according to some embodiments, a depth d3 of a p type impurity doped into the fourth source/drain 340 based on a top surface of a first part 310a of the third fin type active pattern 310 may be substantially equal to a depth d4 of the p type impurity doped into a fifth source/drain 440 based on a top surface of a first part 410a of a fourth fin type active pattern 410.

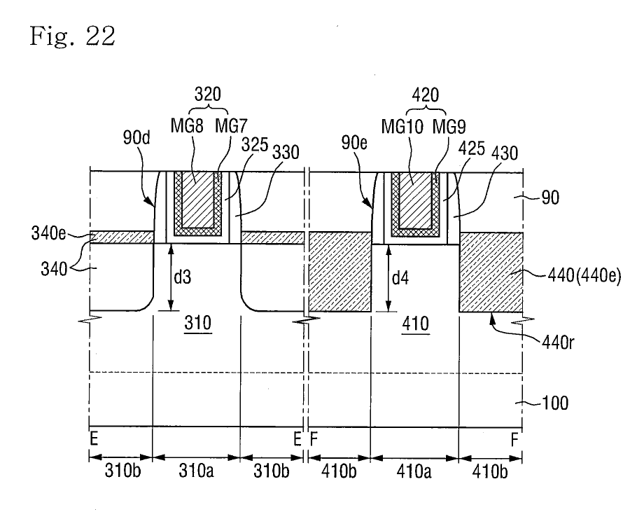

FIG. 23 illustrates cross-sectional views of a semiconductor device 10 according to some embodiments of the present inventive concept. For ease of description, the following description will focus on differences between the semiconductor device 9 of FIG. 21 and the semiconductor device 10 of FIG. 23.

Referring to FIG. 23, a depth d3 of a p type impurity doped into a fourth source/drain 340 is different from a depth d4 of a p type impurity doped into a fifth source/drain 440.

In the semiconductor device 10 according to some embodiments, the depth d4 of the p type impurity doped into the fifth source/drain 440 is greater than the depth d3 of the p type impurity doped into the fourth source/drain 340.

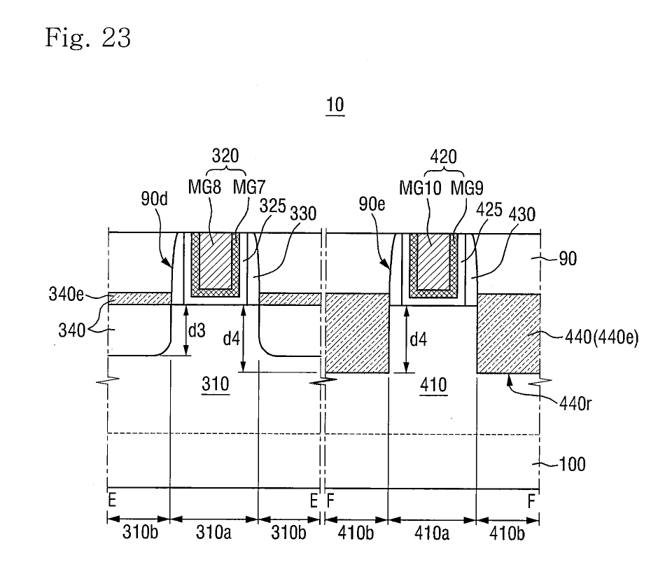

FIGS. 24 and 25 illustrate a semiconductor device 11 according to some embodiments of the present inventive concept. For ease of description, the following description will focus on differences between the semiconductor device 7 of FIG. 18 and the semiconductor device 11 of FIG. 24. In detail, FIG. 24 illustrates perspective views of the semiconductor device 11, and FIG. 25 illustrates cross-sectional views taken along the lines E-E and F-F of FIG. 24.

Referring to FIGS. 24 and 25, a fourth fin type transistor 301 includes a fifth recess 340r and a fourth source/drain 340 formed in the fifth recess 340r.

A third fin type active pattern 310 includes a first part 310a and a second part 310b. A top surface of the second part 310b of the third fin type active pattern 310 is recessed relative to a top surface of the first part 310a of the third fin type active pattern 310. That is to say, a height ranging from a substrate 100 to a top surface of the first part 310a of the third fin type active pattern 310 is greater than a height ranging from the substrate 100 to a top surface of the second part 310b of the third fin type active pattern 310.

A fifth recess 340r may be formed in the third fin type active pattern 310 disposed at both sides of a fourth gate electrode 320. The fifth recess 340r may be formed in the second part 310b of the third fin type active pattern 310.

A fourth source/drain 340 may be formed on the third fin type active pattern 310 disposed at both sides of the fourth gate electrode 320. The fourth source/drain 340 may be formed on the second part 310b of the third fin type active pattern 310. The fourth source/drain 340 may include, for example, a doped p type impurity.

The fourth source/drain 340 may include a fifth epitaxial layer 340e formed in the fifth recess 340r. In the semiconductor device 11 according to some embodiments, outer circumferential surfaces of the fifth epitaxial layer 340e may have at least one of a diamond shape, a circular shape and a rectangular shape. In FIG. 24, the fifth epitaxial layer 340e shaped of a diamond (or a pentagon or a hexagon) is illustrated by way of example.

In the semiconductor device 11 according to some embodiments, the fifth epitaxial layer 340e may include a compressive stress material. For example, the compressive stress material may be a material having a greater lattice constant than silicon (Si), e.g., SiGe. The compressive stress material may improve mobility of carriers of a channel region by applying compressive stress to the third fin type active pattern 310 (e.g., the first part 310a of the third fin type active pattern 310).

A depth d3 of the p type impurity doped into the fourth source/drain 340 is different from a depth d4 doped of the p type impurity doped into the fifth source/drain 440. In the semiconductor device 11 according to some embodiments, the depth d3 of the p type impurity doped into the fourth source/drain 340 is less than the depth d4 doped of the p type impurity doped into the fifth source/drain 440.

FIG. 25 illustrates that a height ranging from a bottommost part of the fourth epitaxial layer 440e to a top surface of the first part 410a of the fourth fin type active pattern 410 is equal to a height ranging from a bottommost part of the fifth epitaxial layer 340e to the top surface of the first part 310a of the third fin type active pattern 310, but aspects of embodiments are not limited thereto.

The height ranging from the bottommost part of the fourth epitaxial layer 440e to the top surface of the first part 410a of the fourth fin type active pattern 410 may be different from the height ranging from the bottommost part of the fifth epitaxial layer 340e to the top surface of the first part 310a of the third fin type active pattern 310. If the height ranging from the bottommost part of the fourth epitaxial layer 440e to the top surface of the first part 410a of the fourth fin type active pattern 410 is smaller than the height ranging from the bottommost part of the fifth epitaxial layer 340e to the top surface of the first part 310a of the third fin type active pattern 310, the p type impurity may be entirely doped into the fifth epitaxial layer 340e of the fourth source/drain 340.

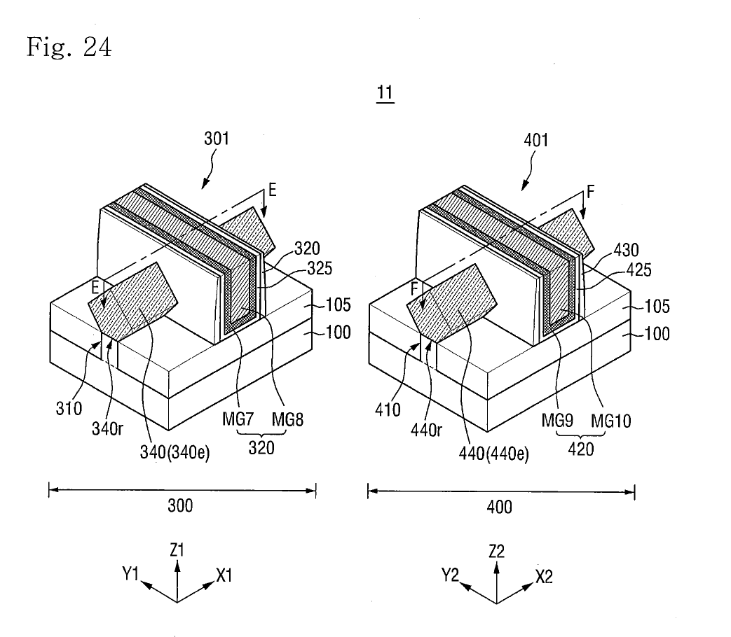

Next, a semiconductor device according to some embodiments will be described with reference to FIGS. 26 to 28.

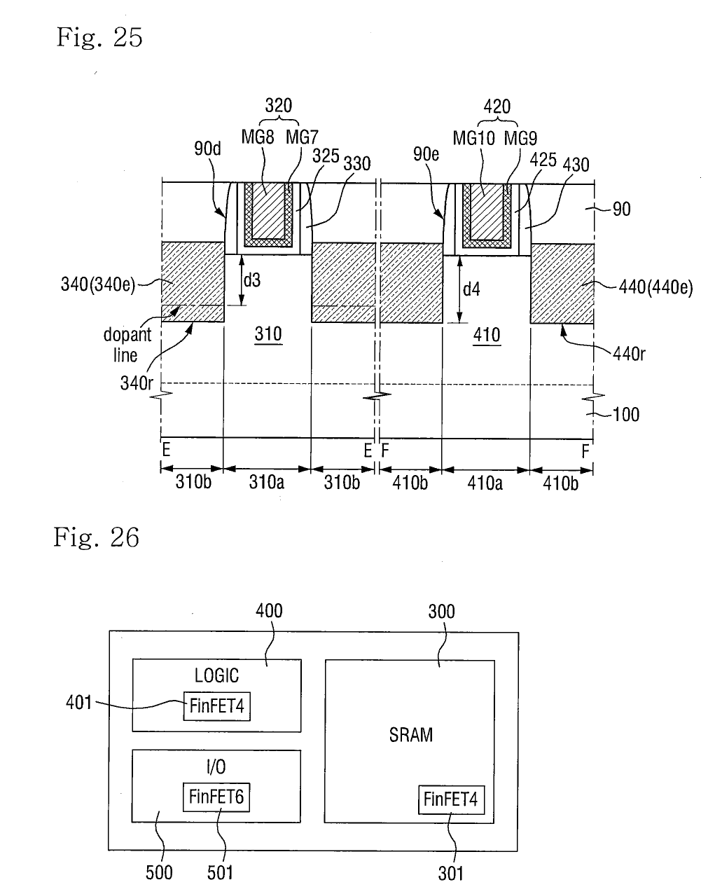

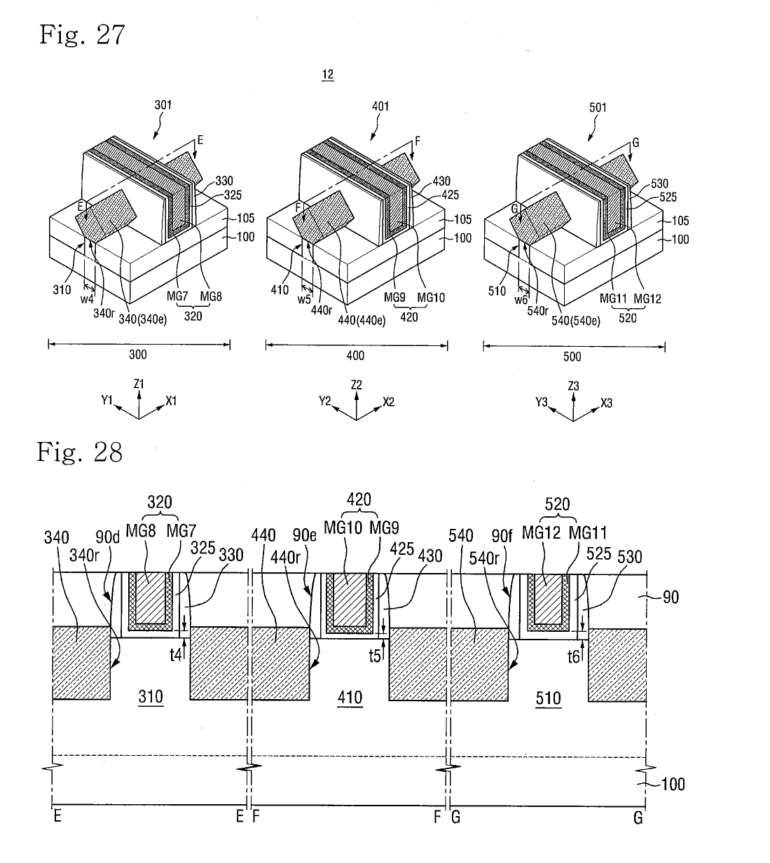

FIG. 26 illustrates a diagram of a semiconductor device according to some embodiments of the present inventive concept, FIG. 27 illustrates perspective views of the semiconductor device of FIG. 26, and FIG. 28 illustrates cross-sectional views taken along the lines E-E, F-F and G-G of FIG. 27.

Referring to FIG. 26, in the semiconductor device 12 according to some embodiments, a fourth fin type transistor 301 may be disposed on an SRAM region 300 and a sixth fin type transistor 501 may be disposed on an I/O region 500.

The fourth fin type transistor 301, the fifth fin type transistor 401 and the sixth fin type transistor 501 may be of the same type each other, that is, n type or p type transistors. In the semiconductor device 12 according to some embodiments, it is assumed that the fourth fin type transistor 301, the fifth fin type transistor 401 and the sixth fin type transistor 501 are p type transistors.

In FIG. 26, the SRAM region 300, the logic region 400 and the I/O region 500 are illustrated by way of example, but not limited thereto.

In the semiconductor device 12 according to some embodiments, the fourth fin type transistor 301 and the fifth transistor 401 are substantially the same with those of the semiconductor device 11 according to some embodiments, except for relation between a depth of the p-type impurities doped into the fourth source/drain 340 and a depth of the p-type impurities doped into the fifth source/drain 440, and repeated descriptions thereof will not be given.

In addition, since the sixth fin type transistor 501 is substantially the same with the fifth fin type transistor 401, the following description will focus on differences therebetween.

Referring to FIGS. 27 and 28, the fourth fin type transistor 301 includes a third fin type active pattern 310, a fourth gate electrode 320 and a fourth source/drain 340. The fifth fin type transistor 401 includes a fourth fin type active pattern 410, a fifth gate electrode 420 and a fifth source/drain 440.

The sixth fin type transistor 501 includes a fifth fin type active pattern 510, a sixth gate electrode 520 and a sixth source/drain 540.

In the semiconductor device 12 according to some embodiments, a thickness t4 of a fourth gate insulation layer 325 is greater than a thickness t5 of the fifth gate insulation layer 425 and a thickness t6 of the sixth gate insulation layer 525 is greater than a thickness t5 of the fifth gate insulation layer 425.

For example, the thickness t4 of a fourth gate insulation layer 325 may be substantially equal to the thickness t6 of the sixth gate insulation layer 525 and greater than the thickness t5 of the fifth gate insulation layer 425.

Alternatively, the thickness t6 of the sixth gate insulation layer 525 may be greater than the thickness t4 of a fourth gate insulation layer 325 and the thickness t4 of a fourth gate insulation layer 325 may be greater than the thickness t5 of the fifth gate insulation layer 425, but aspects of embodiments are not limited thereto.

The third fin type active pattern 310 may have long sides extending in a first direction X1 and short sides extending in a second direction Y1, the fourth fin type active pattern 410 may have long sides extending in a third direction X2 and short sides extending in a fourth direction Y2, and the fifth fin type active pattern 510 may have long sides extending in a fifth direction X3 and short sides extending in a sixth direction Y3.

A short side width of the third fin type active pattern 310 is a fourth width w4, a short side width of the fourth fin type active pattern 410 is a fifth width w5, and a short side width of the fifth fin type active pattern 510 is a sixth width w6.

In the semiconductor device 12 according to some embodiments, the short side width w4 of the third fin type active pattern 310, the short side width w5 of the fourth fin type active pattern 410 and the short side width w6 of the fifth fin type active pattern 510 may be substantially equal to one another.

Next, an electronic system using the semiconductor devices shown in FIGS. 1 to 28 will be described.

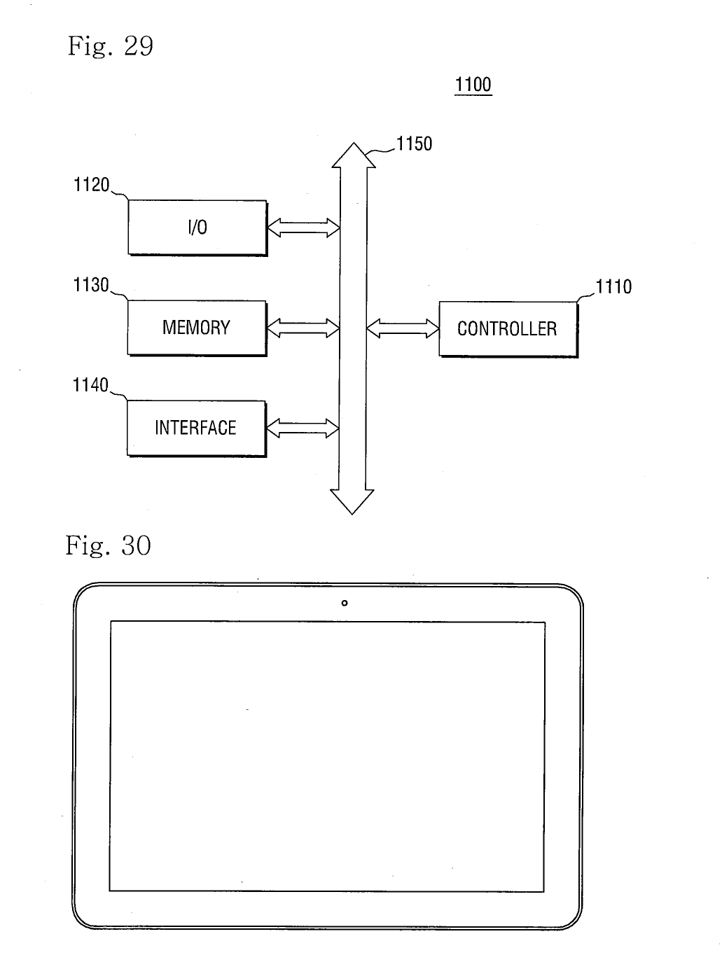

FIG. 29 illustrates a block diagram of an electronic system including semiconductor devices according to some embodiments of the present inventive concept.

Referring to FIG. 29, the electronic system 1100 may include a controller 1110, an input/output device (I/O) 1120, a memory device 1130, an interface 1140 and a bus 1150. The controller 1110, the I/O 1120, the memory device 1130, and/or the interface 1140 may be connected to each other through the bus 1150. The bus 1150 corresponds to a path through which data moves.

The controller 1110 may include at least one of a microprocessor, a digital signal processor, a microcontroller, and logic elements capable of functions similar to those of these elements. The I/O 1120 may include a keypad, a keyboard, a display device, and so on. The memory device 1130 may store data and/or commands. The interface 1140 may perform functions of transmitting data to a communication network or receiving data from the communication network. The interface 1140 may be wired or wireless. For example, the interface 1140 may include an antenna or a wired/wireless transceiver, and so on. Although not shown, the electronic system 1100 may further include high-speed DRAM and/or SRAM as a working memory for improving the operation of the controller 1110 and may further include high-speed DRAM and/or SRAM. The semiconductor devices according to some embodiments of the present invention may be provided in the memory device 1130 or may be provided as some components of the controller 1110 or the I/O 1120.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

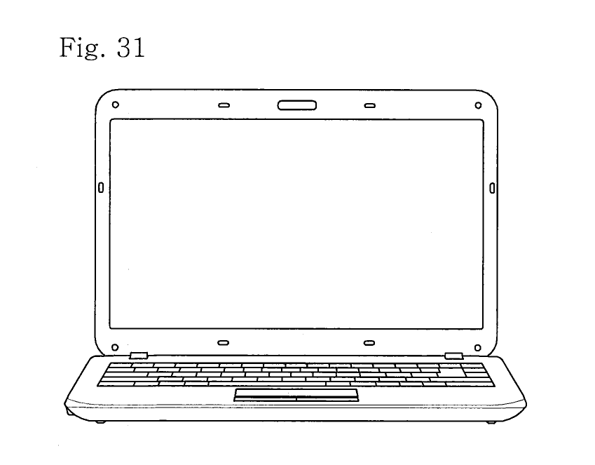

FIGS. 30 and 31 illustrate example semiconductor systems to which semiconductor devices according to some embodiments of the present inventive concept can be applied. FIG. 30 illustrates an example in which each of the semiconductor devices according to some embodiments is applied to a tablet PC, and FIG. 31 illustrates an example in which each of the semiconductor devices according to some embodiments is applied to a notebook computer. At least one of the semiconductor devices according to some embodiments can be employed to a tablet PC, a notebook computer, and the like. It is obvious to one skilled in the art that the semiconductor devices according to some embodiments may also be applied to other IC devices not illustrated herein.

While the present disclosure has been particularly shown and described with reference to some embodiments thereof, it will be understood by those of ordinary skill in the art that various changes in form and details may be made therein without departing from the spirit and scope of the present disclosure as defined by the following claims. It is therefore desired that the present embodiments be considered in all respects as illustrative and not restrictive, reference being made to the appended claims rather than the foregoing description to indicate the scope of the disclosure.

What is claimed is:

1. A semiconductor device comprising:
a substrate comprising a first region and a second region;
a first fin type active pattern on the substrate, extending in a first direction and comprising a first part and a second part, in the first region, the second part being disposed in the first direction at both sides of the first part;
a second fin type active pattern on the substrate, extending in a second direction and comprising a third part and a fourth part, in the second region, the fourth part being disposed in the second direction at both sides of the third part and recessed relative to the third part;
a first gate electrode on the first part and extending in a third direction different from the first direction;
a second gate electrode on the third part and extending in a fourth direction different from the second direction;
a first source/drain in the second part and doped with a first type impurity; and
a second source/drain on the fourth part and comprising a first epitaxial layer doped with the first type impurity.

2. The semiconductor device of claim 1, wherein a top surface of the first part is substantially co-planar with a top surface of the second part.

3. The semiconductor device of claim 1, further comprising a field insulation layer on the substrate, wherein a top surface of the first fin type active pattern upwardly protrudes relative to a top surface of the field insulation layer, and
wherein the first source/drain comprises a second epitaxial layer on a top surface of the second part and a sidewall of the second part upwardly protruding relative to the top surface of the field insulation layer.

4. The semiconductor device of claim 3, wherein both the first epitaxial layer and the second epitaxial layer comprise a material.

5. The semiconductor device of claim 1, wherein a doping depth of the first type impurity from a top surface of the first part is less than a doping depth of the first type impurity from a top surface of the third part.

6. The semiconductor device of claim 1, wherein a doping depth of the first type impurity from a top surface of the first part is substantially equal to a doping depth of the first type impurity from a top surface of the third part.

7. The semiconductor device of claim 1, wherein the first type impurity is a p type impurity.

8. The semiconductor device of claim 1, wherein the first region is an SRAM region, and the second region is a logic region.

9. A semiconductor device comprising:
a first fin type active pattern extending in a first direction and comprising a first part and a second part, on a substrate, the second part being disposed in the first direction at both sides of the first part;
a second fin type active pattern extending in the first direction and comprising a third part and a fourth part, on the substrate, the fourth part being disposed in the first direction at both sides of the third part and recessed relative to the third part;
a gate electrode on the first part and the third part and extending in a second direction different from the first direction;
a first source/drain in the second part and doped with a first type impurity; and
a second source/drain on the fourth part and comprising a first epitaxial layer doped with a second type impurity different from the first type impurity.

10. The semiconductor device of claim 9, wherein a top surface of the first part is substantially co-planar with a top surface of the second part.

11. The semiconductor device of claim 9, further comprising a field insulation layer on the substrate, wherein a top surface of the first fin type active pattern upwardly protrudes relative to a top surface of the field insulation layer, and
wherein the first source/drain further comprises a second epitaxial layer on a top surface of the second part and a sidewall of the second part upwardly protruding relative to the top surface of the field insulation layer.

12. The semiconductor device of claim 11, wherein the first epitaxial layer and the second epitaxial layer comprise different materials.

13. The semiconductor device of claim 9, wherein a doping depth of the first type impurity from a top surface of the first part is less than a doping depth of the second type impurity from a top surface of the third part.

14. The semiconductor device of claim 9, wherein a doping depth of the first type impurity from a top surface of the first part is substantially equal to a doping depth of the second type impurity from a top surface of the third part.

15. The semiconductor device of claim 9, wherein the first type impurity is a p type impurity, and the second type impurity is an n type impurity.

16. A semiconductor device comprising:
a substrate comprising a first region and a second region;
a first fin type transistor on the first region, the first fin type transistor comprising a first fin type active pattern, a first gate electrode crossing the first fin type active pattern and a first source/drain that is disposed at both sides of the first gate electrode and doped with a first type impurity; and
a second fin type transistor on the second region, the second fin type transistor comprising a second fin type active pattern, a second gate electrode crossing the second fin type active pattern and a second source/drain that is disposed at both sides of the second gate electrode and doped with a second type impurity,
wherein a first doping depth of the first type impurity from a top surface of the first fin type active pattern overlapping with the first gate electrode is different from a second doping depth of the second type impurity from a top surface of the second fin type active pattern overlapping with the second gate electrode.

17. The semiconductor device of claim 16, wherein the first fin type transistor further comprises a first recess that is in the first fin type active pattern and is disposed at one of sides of the first gate electrode,
wherein the second fin type transistor further comprises a second recess that is in the second fin type active pattern and is disposed at one of sides of the second gate electrode, and
wherein the first source/drain comprises a first epitaxial layer in the first recess, and the second source/drain comprises a second epitaxial layer in the second recess.

18. The semiconductor device of claim 16, wherein each of the first type impurity and the second type impurity is a p type impurity, and
wherein the first region is an SRAM region, and the second region is a logic region.

19. The semiconductor device of claim 16, wherein the first type impurity is a p type impurity, and the second type impurity is an n type impurity, and
wherein the first fin type transistor is a pull-up transistor of a SRAM, and the second fin type transistor is a pull-down transistor or a pass transistor of the SRAM.

20. The semiconductor device of claim 16, wherein the second doping depth is greater than the first doping depth.
